(19) United States
(12) Patent Application Publication
(10) Pub. No.: US 2024/0317475 A1
(43) Pub. Date: Sep. 26, 2024

(54) ELECTRONIC ARTICLE PACKAGING SHEET

(71) Applicant: DENKA COMPANY LIMITED, Tokyo (JP)

(72) Inventors: Ikuka INODA, Tokyo (JP); Takeshi SAITO, Tokyo (JP); Ryosuke YANAKA, Tokyo (JP)

(73) Assignee: DENKA COMPANY LIMITED, Tokyo (JP)

(21) Appl. No.: 18/269,867

(22) PCT Filed: Dec. 14, 2021
(86) PCT No.: PCT/JP2021/046017

§ 371 Date: Jun. 27, 2023

(30) Foreign Application Priority Data
Jan. 8, 2021 (JP) 2021-001937

(51) Int. Cl. B65D 65/40; B65D 85/68

(52) U.S. Cl. CPC B65D 65/40; B65D 85/68; B65D 2585/86

(57) ABSTRACT

An electronic device packaging sheet provided with a substrate sheet in which a substrate layer A and a substrate layer B are alternately laminated, wherein: the thickness of an individual substrate layer A is 10-60 μm; the thickness of an individual substrate layer B is 1-50 μm; the average value of the thickness of an individual substrate layer A is greater than the average value of the thickness of an individual substrate layer B; and the substrate layer A and the substrate layer B include a different thermoplastic resin as a main component.

### TECHNICAL FIELD

The present invention relates to an electronic article packaging sheet.

### BACKGROUND

Trays (injection trays, vacuum-molded trays, etc.), magazines, and carrier tapes (embossed carrier tapes), etc., are used as packaging containers for semiconductors and electronic devices, in particular, for integrated circuits (IC) and electronic devices comprising an IC, etc. Polystyrene-based resins, ABS-based resins, polyvinyl chloride-based resins, polypropylene-based resins, polyester-based resins, polyphenylene ether-based resins, and polycarbonate-based resins, etc., are used as thermoplastic resins constituting the packaging containers for the foregoing electronic devices. Further, from the viewpoint of avoiding IC damage or breakage due to static electricity, there have also been proposed, for example, packaging containers which have, provided to a surface of a substrate layer comprising an ABS-based resin a conductive layer comprising a resin with a conductive agent such as conductive carbon black blended therein (Patent Documents 1 and 2, etc.).

The trays and carrier plates mentioned above are obtained by using a publicly-known method to mold sheets for packaging electronic devices. However, at the time of molding, in particular, when slitting an original sheet or when punching out sprocket holes, etc., fluffs or burrs may be generated. Such fluffs and burrs sometimes cause faults in electronic devices by falling into accommodation sections (pockets) and adhering to the electronic devices. In recent years, accompanying the miniaturization of electronic devices, there is stronger demand for a reduction in faults caused by burrs or fluffs adhering to electronic devices.

To address the foregoing problem, blending a polyolefin, a styrene-butadiene-styrene block copolymer, or a styrene-ethylene-butylene-styrene block copolymer, etc., in a substrate layer or a conductive layer has been proposed (for example, Patent Documents 3 and 4, etc.). However, in conventional methods, burrs and fluffs are not sufficiently inhibited. Further, in methods wherein the generation of burrs and fluffs is inhibited by changing a resin constitution, depending on the constitution, there are cases in which moldability of the sheet decreases and it is difficult to mold a pocket in a desired shape.

### CITATION LIST

### Patent Literature

Patent Document 1: JP H9-174769 A
Patent Document 2: JP 2002-292805 A
Patent Document 3: WO 2006/030871 A
Patent Document 4: JP 2003-170547 A

### SUMMARY OF INVENTION

### Technical Problem

Thus, the objective of the present invention is to provide: an electronic device packaging sheet which can effectively inhibit the generation of fluffs and burrs while also maintaining good moldability; and a molded article comprising the sheet.

### Solution to Problem

To address the problem described above, the present inventors carried out diligent research which resulted in the discovery that all of the problems described above can be solved by an electronic device packaging sheet provided with a substrate sheet having a multilayer structure in which a substrate layer A and a substrate layer B that include different thermoplastic resins are alternately laminated, and in which the average value of the thickness of an individual substrate layer A is set so as to be greater than the average value of the thickness of an individual substrate layer B, and thus, were able to complete the present invention.

That is, the present invention has the following embodiments.
(1) An electronic device packaging sheet provided with a substrate sheet in which a substrate layer A and a substrate layer B are alternately laminated, wherein: the thickness of an individual substrate layer A is 10-60 μm; the thickness of an individual substrate layer B is 1-50 μm; the average value of the thickness of an individual substrate layer A is greater than the average value of the thickness of an individual substrate layer B; and the substrate layer A and the substrate layer B include a different thermoplastic resin as a main component.
(2) The electronic device packaging sheet described in (1), wherein the number of alternately laminated layers of the substrate layer A and the substrate layer B is 3-70.
(3) The electronic device packaging sheet described in (1) or (2), wherein the average value of the thickness of an individual substrate layer A is 1.001 times or more the average value of the thickness of an individual substrate layer B.
(4) The electronic device packaging sheet described in any one of (1) to (3), wherein the substrate layer A includes an ABS-based resin as a main component.
(5) The electronic device packaging sheet described in any one of (1) to (4), wherein the substrate layer B includes a thermoplastic resin other than an ABS-based resin as a main component.
(6) A molded article comprising the electronic device packaging sheet described in any one of (1) to (5).
(7) The molded article described in (6), wherein the molded article is a container.
(8) The molded article described in (6), wherein the molded article is a carrier tape.

### Effects of Invention

According to the present invention, it is possible to provide: an electronic device packaging sheet which can effectively inhibit the generation of fluffs and burrs while also maintaining good moldability; and a molded article comprising the sheet.

### BRIEF DESCRIPTION OF DRAWINGS

FIG. 1 illustrates evaluation criteria for moldability of an electronic device packaging sheet according to an embodiment of the present invention.

### DESCRIPTION OF EMBODIMENTS

The present invention shall be explained in more detail below, but the present invention is not limited to the following embodiments.

### [Electronic Device Packaging Sheet]

An electronic device packaging sheet (hereinafter also referred to as simply a “sheet”) according to the present invention is an electronic device packaging sheet provided with a substrate sheet in which a substrate layer A and a substrate layer B are alternately laminated, the electronic device packaging sheet being characterized in that: the thickness of an individual substrate layer A is 10-60 μm; the thickness of an individual substrate layer B is 1-50 μm; the average value of the thickness of an individual substrate layer A is greater than the average value of the thickness of an individual substrate layer B; and the substrate layer A and the substrate layer B include a different thermoplastic resin as a main component. The electronic device packaging sheet according to the present invention can effectively inhibit the generation of fluffs and burrs while also maintaining good moldability.

### (Substrate Sheet)

The electronic device packaging sheet according to the present invention is provided with a substrate sheet. The substrate sheet is a substrate sheet having a multilayer structure in which the substrate layer A and the substrate layer B are alternately laminated. By being provided with a substrate sheet having such a multilayer structure, the electronic device packaging sheet according to the present invention can effectively inhibit the generation of burrs and fluffs. Further, moldability when the electronic device packaging sheet is molded as a carrier tape, etc., does not decrease and it is possible to mold a pocket having a desired shape.

The number of alternately laminated layers of the substrate A and the substrate B, that is, the total number of laminated layers in the substrate sheet, is not particularly limited as long as the effects of the present invention are exhibited. From the viewpoint of controlling the thickness of each layer during substrate sheet film formation, the total number of laminated layers is preferably 3-70, more preferably 4-60, and more preferably 5-30. If the total number of laminated layers in the substrate sheet is 3-70, it becomes easy to obtain a substrate sheet having a desired thickness while also inhibiting the generation of burrs and fluffs.

In one embodiment, the total number of laminated substrate layers A is preferably greater than the total number of laminated substrate layers B. By designing so that the total number of laminated substrate layers A is greater than the total number of laminated substrate layers B, the resin layers constituting the two surfaces of the substrate sheet are both a substrate layer A. By having such a configuration, when, for example, another layer such as a conductive layer, etc., is provided to the two surfaces of the substrate sheet, adhesion between the substrate sheet and the other layer is likely to be good.

### <Substrate Layer A and Substrate Layer B>

The substrate layer A and the substrate layer B constituting the substrate sheet include a different thermoplastic resin as a main component. Here, “includes as a main component” means that the ratio of the thermoplastic resin in the resin composition (100 mass %) constituting the substrate layer A or the substrate layer B is 50 mass % or more. In one embodiment, the ratio of the thermoplastic resin in the resin composition constituting the substrate layer A or the substrate layer B may be 100 mass %. Further, “a different thermoplastic resin” includes not only thermoplastic resins which differ in terms of thermoplastic resin type but also thermoplastic resins which differ in terms of the physical properties thereof. That is, the substrate layer A and the substrate layer B may include, as a main component, thermoplastic resins of a different type, and may include, as a main component, thermoplastic resins of the same type but having different physical properties. From the viewpoint that it becomes easy to confirm the thickness of each layer during substrate sheet film formation, it is preferable for the substrate layer A and the substrate layer B to respectively include thermoplastic resins of a different type as a main component.

### (Thermoplastic Resin)

Examples of the thermoplastic resin include polystyrene-based resins (PS-based resins), ABS-based resins, polyester-based resins, polycarbonate-based resins (PC-based resins), and acrylonitrile-styrene bipolymers (AS-based resins), etc. These thermoplastic resins may be used alone or as a combination of two or more.

Examples of the PS-based resins include polystyrene resins and rubber-modified styrene resins (rubber-g-styrene-based resins (GPPS) or high-impact styrene resins (HIPS)), etc. The PS-based resins may be used alone or as a combination of two or more.

Examples of aromatic vinyl monomers for forming a PS-based resin include styrene, alkyl-substituted styrenes (for example, vinyl toluene, vinyl xylene, p-ethylstyrene, p-isolpropylstyrene, butylstyrene, p-t-butylstyrene, etc.), halogen-substituted styrenes (for example, chlorostyrene, bromostyrene, etc.), and a-alkyl-substituted styrenes having an alkyl group substituted in the a position (for example, a-methylstyrene, etc.), etc. These aromatic vinyl monomers may be used alone or as a combination of two or more. Among these monomers, it is normally preferable to use styrene, vinyl toluene, or α-methylstyrene, etc., in particular, styrene.

The MFR of the PS-based resin, measured in accordance with the specifications of ISO 1133, is preferably 1-30 g/10 min and more preferably 2-25 g/10 min.

ABS-based resins have, as a main component, a terpolymer of diene-based rubber-aromatic vinyl monomer-vinyl cyanide monomer, and a representative example thereof is a resin or resin composition having an acrylonitrile-butadiene-styrene terpolymer as a main component. Specific examples thereof include: an acrylonitrile-butadiene-styrene terpolymer; and a mixture of an acrylonitrile-butadiene-styrene terpolymer and an acrylonitrile-styrene bipolymer, etc. Among the foregoing, as the ABS-based resin, it is preferable to use an acrylonitrile-butadiene-styrene terpolymer, and it is more preferable to use a mixture of an acrylonitrile-butadiene-styrene terpolymer and an acrylonitrile-styrene bipolymer. In addition to the monomer units described above, the foregoing polymers also include polymers containing a monomer such as α-methylstyrene, vinyl toluene, dimethylstyrene, chlorostyrene, vinylnaphthalene, etc., as a trace component of the styrene-based monomer. Further, the foregoing polymers also include polymers containing a monomer such as methacrylonitrile, ethacrylonitrile, fumaronitrile, etc., as a trace component of the vinyl cyanide monomer. Although the following description does not include a description of the trace component, polymers containing these components in a range that does not hinder the effects of the invention of the present application are also included. The ABS-based resin may be used alone or as a combination of two or more. The MFR of the ABS-based resin, measured in accordance with the specifications of ISO 1133, is preferably 1-30 g/10 min and more preferably 2-25 g/10 min.

Examples of the polyester-based resins include polyester resins obtained from a polyfunctional glycol and an aromatic polyfunctional carboxylic acid or an aliphatic polyfunctional carboxylic acid, and hydroxycarboxylic acid-based polyester resins, etc. Examples of the polyester resins obtained from a polyfunctional glycol and an aromatic polyfunctional carboxylic acid or an aliphatic polyfunctional carboxylic acid include polyethylene terephthalate, polybutylene terephthalate, polyethylene naphthalate, polybutylene naphthalate, polyethylene adipate, polybutylene adipate, and other copolymers thereof, etc. Examples of the other copolymers thereof include polyester resins obtained by copolymerizing a polyalkylene glycol, polycaprolactone, or the like. Examples of the hydroxycarboxylic acid-based polyester resins include polylactic acid, polyglycolic acid, and polycaprolactone, etc. In the present invention, it is also possible to use a copolymer of the polyester resins described as examples above. The polyester-based resin may be used alone or as a combination of two or more.

The MFR of the polyester-based resin, measured in accordance with the specifications of ISO 1133, is preferably 1-30 g/10 min and more preferably 2-25 g/10 min.

PC-based resins are resins derived from dihydroxy compounds, and thereamong, a resin derived from an aromatic dihydroxy compound is preferable, in particular, an aromatic dihydroxy compound (bisphenol) in which two aromatic dihydroxy compounds are bonded via a kind of binding group is preferable. For these PC-based resins, it is possible to use a resin manufactured by a publicly-known manufacturing method, and the manufacturing method is not particularly limited. Further, a commercially available resin may also be used. The PC-based resin may be used alone or as a combination of two or more.

The MFR of the PC-based resin, measured in accordance with the specifications of ISO 1133, is preferably 1-30 g/10 min and more preferably 2-25 g/10 min.

The AS-based resin is a resin which includes, as a main component, a bipolymer of acrylonitrile and a styrene-based monomer. Examples of the styrene-based monomer unit include styrene, alkyl-substituted styrenes (for example, vinyl toluene, vinyl xylene, p-ethylstyrene, p-isopropylstyrene, butylstyrene, p-t-butylstyrene, etc.), halogen-substituted styrenes (for example, chlorostyrene, bromostyrene, etc.), and a-alkyl-substituted styrenes having an alkyl group substituted in the a position (for example, a-methylstyrene, etc.), etc. These styrene-based monomers may be used alone or as a combination of two or more. Among these styrene monomers, it is normally preferable to use styrene, vinyl toluene, or a-methylstyrene, etc., in particular, styrene.

The substrate layer A and the substrate layer B are preferably configured from a resin composition including, as a main component, at least one resin selected from the thermoplastic resins described above. For example, when the substrate layer A or the substrate layer B includes, as a main component, a PS-based resin as the thermoplastic resin, the PS-based resin may have mixed therein, as a modifier in a range not exceeding 50 mass %, for example, a block copolymer of styrene and a diene such as a styrene-butadiene (SB) block copolymer, or an olefin-styrene block copolymer or a polyolefin, which are hydrogenated products thereof. Further, when the substrate layer A or the substrate layer B includes, as a main component, a polycarbonate-based (PC-based) resin as the thermoplastic resin, the PC-based resin may have mixed therein, as a modifier in a range not exceeding 50 mass %, an ABS resin, a polyethylene terephthalate resin, a polybutylene terephthalate resin, etc. Similarly, when an ABS-based resin or a polyester-based resin is included, resin components may also be added as various kinds of modifiers in a range not exceeding 50 mass %. Furthermore, it is also possible to add various kinds of additives such as lubricants, plasticizers, processing aids, etc., as needed.

The DuPont impact strength of the substrate layer B is preferably higher than the DuPont impact strength of the substrate layer A. Further, the difference between the DuPont impact strength of the substrate layer A and that of the substrate layer B is preferably 0.2 J or more and more preferably 0.5 J or more. If the impact strengths of the substrate layer A and the substrate layer B are in the above ranges, it becomes easy to separate layers at a boundary of the substrate layer A and the substrate layer B and it becomes easy to inhibit the generation of burrs and fluffs more effectively. Note that the DuPont impact strength of the substrate layers A and B indicates a value measured in accordance with the DuPont impact strength measurement method of JIS K 5400.

In one embodiment, the thermoplastic resin included in the substrate layer A is preferably an ABS-based resin. If the substrate layer A is a layer including an ABS-based resin as a main component, then for an electronic device packaging sheet obtained therefrom, it becomes easy to maintain moldability and it becomes easy to inhibit burrs more effectively.

The ratio of the ABS-based resin included in the substrate layer A is preferably 50 mass % or more, more preferably 60-100 mass %, and particularly preferably 75-100 mass % with respect to the total mass of the resin composition constituting the substrate layer A. Further, from the viewpoint of strength and moldability, an ABS-based resin having a butadiene rubber content ratio of 5-30% is more preferable.

The substrate layer A may include an ABS-based resin and another thermoplastic resin. As the other thermoplastic resin, PC-based resins and polyester-based resins are preferable, with PC-based resins being more preferable. When the substrate layer A includes an ABS-based resin and the other thermoplastic resin, the ratio of the ABS-based resin to the other thermoplastic resin (ABS-based resin/other thermoplastic resin) in the resin composition constituting the substrate layer A may be in the range 99/1-50/50.

Further, the substrate layer B is preferably a layer including a thermoplastic resin other than an ABS-based resin as a main component. If the substrate layer B is a layer including a thermoplastic resin other than an ABS-based resin as main component, it becomes easy to inhibit the generation of burrs and fluffs more effectively. PC-based resins and polyester-based resins are preferable as the thermoplastic resin included in the substrate layer B, with PC-based resins being more preferable.

When the substrate layer B includes a PC-based resin, the ratio of the PC-based resin in the resin composition constituting the substrate layer B is preferably 50 mass % or more, more preferably 60-100 mass %, and particularly preferably 75-100 mass % with respect to the total mass of the resin composition.

In one embodiment, it is preferable that the substrate layer A is a layer including an ABS-based resin as a main component and that the substrate layer B is a layer including a PC-based resin as a main component.

Further, the substrate layer B may include an ABS-based resin. At that time, the substrate layer A may also include an ABS-based resin as a main component.

Further, when the substrate layer A includes an ABS resin as a main component, the substrate layer B may include an acrylonitrile-styrene bipolymer as a main component.

### (Layer Thickness)

The thickness of an individual substrate layer A constituting the substrate sheet is 10-60 μm, preferably 15-50 μm, and more preferably 20-45 μm. Further, the thickness of an individual substrate layer B is 1-50 μm, preferably 5-40 μm, and more preferably 10-30 μm. Furthermore, in the electronic device packaging sheet according to the present invention, the average value of the thickness of an individual substrate layer A is greater than the average value of the thickness of an individual substrate layer B. By thus alternately laminating substrate layers A and B, which include a different thermoplastic resin as a main component, and setting the average value of the thickness of an individual substrate layer A so as to be greater than the average value of the thickness of an individual substrate layer B, it becomes possible to effectively inhibit the generation of burrs and fluffs when punching-out is performed on a sheet. Note that the “thickness of an individual layer” herein indicates a maximum value of the thickness of each layer. The thickness of individual substrate layers A and B in the substrate sheet can be confirmed, for example, by using a microscope, or the like, to observe a cross-section of the substrate sheet.

Individual substrate layers A included in the substrate sheet may all have the same thickness or each layer may have a different thickness. From the viewpoint that winding creases are not readily created when a sheet is wound, it is preferable that individual substrate layers A all have the same thickness. Similarly, individual substrate layers B may all have the same thickness or each layer may have a different thickness. However, from the viewpoint that winding creases are not readily created when a sheet is wound, it is preferable that individual substrate layers B all have the same thickness.

It is inferred that burrs and fluffs generated when a sheet is molded are generated due to the resin being extended when punching-out of the sheet is performed. If the thickness of a substrate section of a sheet is made thinner, the generation of burrs and fluffs is relatively inhibited. However, when the thickness of the substrate section is simply made thinner, it becomes difficult to achieve the various physical properties demanded of an electronic device packaging sheet. The present inventors discovered that by configuring the substrate sheet as a multilayer structure and making the thickness of one layer thinner, it is possible to inhibit the generation of burrs and fluffs caused by extension of the resin. Furthermore, the present inventors discovered that by alternately laminating the two kinds of substrate layers A and B described above which include different thermoplastic resins as a main component, and designing the average value of the thickness of an individual substrate layer A so as to be greater than the average value of the thickness of an individual substrate layer B, it is possible to inhibit the generation of burrs and fluffs more effectively. In the electronic device packaging sheet according to the present invention provided with such a configuration, the substrate layer B serves as a substrate layer A “dividing layer”, and it is possible to effectively inhibit extension of the substrate layer A. Furthermore, the electronic device packaging sheet according to the present invention provided with such a substrate sheet also has good moldability.

The average value of the thickness of an individual substrate layer A is preferably 10-60 μm, preferably 15-50 μm, and more preferably 20-45 μm. Further, the average value of the thickness of an individual substrate layer B is preferably 1-50 μm, preferably 5-40 μm, and more preferably 10-30 μm. Here, the “average value of the thickness of an individual substrate layer A” indicates a value obtained by dividing the total thickness of the substrate layers A in the substrate sheet by the number of substrate layers A laminated therein. That is, when “a1” is the thickness of one substrate layer A, the “average value of the thickness of an individual substrate layer A” means a value calculated by (a1+a2+a3+ . . . +an)/n. Here, “n” indicates the total number of substrate layers A laminated in the substrate sheet. The same also applies with respect to the substrate layer B.

The average value of the thickness of an individual substrate layer A is preferably 1.001 times or more the average value of the thickness of an individual substrate layer B. Although the upper limit thereof is not particularly limited as long as the effects of the present invention are exhibited, from the viewpoint of film formability, no more than 20.0 times is preferable. In one embodiment, the average value of the thickness of an individual substrate layer A is more preferably 1.001-20 times, even more preferably 1.01-15.0 times, and particularly preferably 1.05-12.0 times the average value of the thickness of an individual substrate layer B. By setting the average value of the thickness of an individual substrate layer A so as to be within the ranges described above, it becomes easy to inhibit burrs and fluffs more effectively.

From the viewpoint of moldability and strength when configured as a carrier tape, the thickness of the substrate sheet is preferably 50-700 μm, more preferably 75-600 μm, and particularly preferably 90-450 μm.

The electronic device packaging sheet according to the present invention may be configured solely from the substrate sheet described above. When the electronic device packaging sheet according to the present invention is to be configured as a conductive sheet, a conductive layer may be formed on at least one surface of the substrate sheet. Further, an optional layer (for example, an anti-fouling layer, etc.) may also be provided on the substrate sheet.

### (Conductive Layer)

The electronic device packaging sheet according to the present invention may be provided with a conductive layer on at least one surface of the substrate sheet. The conductive layer is a layer configured from a resin composition including a conductive component.

As long as the effects of the present invention are exhibited, there are no particular limitations for the resin composition constituting the conductive layer. Examples thereof include a resin composition which includes the thermoplastic resin described above at 65-95 mass % and preferably 70-90 mass %, and a conductive agent such as carbon black, or the like, at 5-35 mass % and preferably 10-30 mass % with respect to the total mass of the resin composition.

Examples of the carbon black include furnace black, channel black, and acetylene black, etc., and the carbon black preferably has a large specific surface area and provides high conductivity with a small amount thereof added. Specifically, the carbon black preferably has an average primary particle diameter of 20-100 nm and more preferably 25-65 nm. The average primary particle diameter means an average diameter of particles measured by using a transmission electron microscope.

When a conductive layer is provided, the thickness thereof is not particularly limited. From the viewpoint that the mechanical strength of the electronic device packaging sheet is easily improved, the thickness of the conductive layer is preferably 3-100 μm and more preferably 10-50 μm.

### [Method for Producing Electronic Device Packaging Sheet]

The same method as that used to produce a general multilayer sheet may be used as the method for producing the electronic device packaging sheet according to the present invention. For example, a method disclosed in JP 2007-307893 A, etc., may be employed. Specifically, a resin composition for forming the substrate layer A and a resin composition for forming the substrate layer B are each supplied to a separate extruder and melt-kneaded, then supplied to a feed block, and laminated so that the substrate layer A and the substrate layer B lie on top of one another alternately. At that time, a substrate sheet with a multilayer structure is fabricated by laminating preferably 3-70 layers while adjusting extrusion amounts so that the thickness of an individual substrate layer A is in the range 10-60 μm, the thickness of an individual substrate layer B is in the range 1-50 μm, and the average value of the thickness of an individual substrate layer A is greater than the average value of the thickness of an individual substrate layer B. When the electronic device packaging sheet according to the present invention is to be configured as a conductive sheet, the electronic device packaging sheet can be configured by laminating a resin composition for forming a conductive layer on one surface or both surfaces of the substrate sheet, said resin composition having been melt-kneaded with another extruder.

### [Molded Article]

The electronic device packaging sheet according to the present invention can be configured as a molded article by being molded using a publicly-known method such as vacuum molding, pressure molding, and press-molding, etc. Preferred examples of the molded article of the electronic device packaging sheet include containers and carrier tapes (embossed carrier tapes), etc., for accommodating electronic devices. The electronic device packaging sheet according to the present invention can be used to obtain molded articles in which the generation of cross-sectional fluffs and burrs when the sheet is slit and when sprocket holes, etc., are punched out is extremely low. The electronic device packaging sheet according to the present invention is extremely useful for embossing carrier tapes. In addition, by using the foregoing molding techniques and secondary processing, it is possible to produce embossed carrier tapes which have excellent dimensional accuracy in slit width, punched-out hole diameter etc., and which significantly inhibit the generation of burrs when punching out is performed.

More specifically, in secondary processing steps of slitting and punching out carried out on an embossed carrier tape, etc., which is a molded article of the electronic device packaging sheet according to the present invention, it is possible to obtain sprocket holes which have hole dimensional stability and in which the generation of fluffs and burrs is significantly inhibited for punching out process conditions wherein pin/die one side clearance is a constant wide range between 5-50 μm and punching out speed is in a wide range of 10-300 mm/sec. Further, in a slitting step using a ring-shaped combination blade, too, it is possible to obtain slit edge surfaces which have sheet width stability and no fluffs or burrs.

Furthermore, since the electronic device packaging sheet according to the present invention has good moldability, when molding a pocket for accommodating an electronic device, it is possible to mold a pocket having a desired shape. Specifically, it is possible to mold a pocket which has a desired angle necessary for accommodating an electronic device stably therein, and in which perforations do not occur in the bottom section or wall sections thereof.

The container and embossed carrier tape according to the present invention can be used in the storage and transportation of electronic devices as a carrier tape body in which an electronic device is accommodated in an accommodation section formed by the molding method described above and which is then covered with a cover tape and wound up in a reel form.

A more preferred embodiment of the electronic device packaging sheet according to the present invention is an electronic device packaging sheet provided with a substrate sheet having a multilayer structure in which a substrate layer A including an ABS-based resin as a main component and a substrate layer B including a PC-based resin or a PS-based resin as a main component are alternately laminated, wherein: both surfaces of the substrate sheet are configured from the substrate layer A; the thickness of an individual substrate layer A is 10-60 μm; the thickness of an individual substrate layer B is 1-50 μm; and the average value of the thickness of an individual substrate layer A is greater than the average value of the thickness of an individual substrate layer B. Even more preferably, the average value of the thickness of an individual substrate layer A is 1.001 times or more and 10.000 times or less the average value of the thickness of an individual substrate layer B.

### EXAMPLES

The present invention shall be explained in more detail below by providing examples, but the present invention is not limited by the following descriptions.

### [Fabrication of Electronic Device Packaging Sheet]

### Examples 1-13 and Comparative Examples 1-7

For Examples 1-13 and Comparative Examples 1-7, the raw materials shown for the constitutions of the substrate layer A and the substrate layer B in Tables 1 and 2 were prepared, and furthermore, for Examples 9 and 10, the raw materials were weighed so as to achieve the constitution ratios (mass %) shown in Table 1, and rendered to a homogeneous mixture with a high-speed mixer. Further, for the conductive layer, resin compositions obtained by using a φ45 mm vented twin extruder to knead 80 mass % of a polycarbonate resin (product name “Panlite® L-1225L”, manufactured by Teijin Ltd.) and 20 mass % of acetylene black (product name “Denka Black® granular”, manufactured by Denka Co. Ltd., average primary particle diameter: 35 nm) and pelletizing by a strand cutting method were used.

First, an electronic device packaging sheet was obtained by forming a conductive layer on both surfaces of a substrate sheet having the substrate layer A and the substrate layer B alternately laminated therein using the resin compositions described in Tables 1 and 2, the resin composition for the conductive layer, and a feed block method using a φ65 mm extruder (L/D=28), a φ50 mm extruder (L/D=28), a φ40 mm extruder (L/D=26), and a T-die with a width of 500 mm. Note that the thickness and number of the individual substrate layers A and B, the thickness of the conductive layer, the thickness of the substrate sheet, and the total thickness of the obtained electronic device packaging sheet were as shown in Tables 1 and 2.

### Example 14

Example 14 is an example of an electronic device packaging sheet that does not have a conductive layer.

An electronic device packaging sheet was obtained by fabricating a substrate sheet having the substrate layer A and the substrate layer B alternately laminated therein by using the resin compositions described in Table 1 and a feed block method using a q 65 mm extruder (L/D=28), a φ50 mm extruder (L/D=28), and a T-die with a width of 500 mm.

The thickness and number of the individual substrate layers A and B, the thickness of the substrate sheet, and the total thickness of the obtained electronic device packaging sheet were as shown in Table 1.

The details of the raw materials shown in Tables 1 and 2 are as described below.
a-1: Acrylonitrile-butadiene-styrene copolymer (ABS): product name “SE-10”, manufactured by Denka Co., Ltd.
a-2: Polycarbonate resin (PC): product name “Panlite L-1225L”, manufactured by Teijin Ltd.
a-3: High-impact polystyrene resin (HIPS): product name “E640N”, manufactured by Toyo-Styrene Co., Ltd.
b-1: Polycarbonate resin (PC): product name “Panlite L-1225L”, manufactured by Teijin Ltd.
b-2: Acrylonitrile-butadiene-styrene copolymer (ABS): product name “SE-10”, manufactured by Denka Co., Ltd.

Note that the average primary particle diameter of acetylene black in the conductive layer is a value determined by the method described below.

First, a dispersion sample was prepared by using an ultrasonic disperser to disperse acetylene black in chloroform for 10 minutes under conditions of 150 kHz and 0.4 KW. This dispersion sample was sprinkled and fixed on a carbon-reinforced support film, and an image thereof was then captured with a transmission electron microscope (JEM-2100, manufactured by JEOL Ltd). 1,000 or more particle diameters (maximum diameter for shapes other than a sphere) of an inorganic filler were measured randomly by using an Endter device from an image magnified to 50,000-200,000 times, and the average value thereof was used as the average primary particle diameter.

### [Evaluation of Electronic Device Packaging Sheet]

The electronic device packaging sheets obtained in each of the examples were cut in the extrusion direction of the sheets to fabricate sheet samples which were left for 24 hours in an environment with a temperature of 23° C. and a relative humidity of 50%. Thereafter, film formability and punching-out burr physical properties were evaluated under the conditions described below.

### (1) Moldability

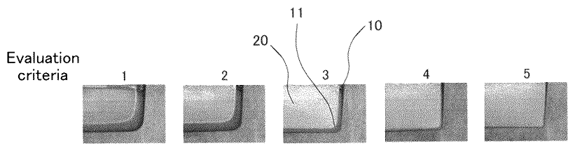

Using a vacuum rotary former (product name: “CT 8/24”, manufactured by Mühlbauer) in conditions with a heater temperature of 450° C., molding of sheet samples slit into 8 mm widths was performed in an environment with a temperature of 23° C. and a relative humidity of 50% to fabricate carrier tapes with 8 mm widths. The pocket size of the carrier tapes was 3 mm in the flow direction, 3 mm in the width direction, and 1 mm in the depth direction. Pockets in obtained molded articles were observed with a microscope, and the sharpness of the angles of the pockets (periphery of the bottom wall section) was evaluated using five stages in accordance with the evaluation criteria shown in FIG. 1. That is, the sharpness of a pocket angle 11 of a pocket 20 in a molded article (carrier tape) 10 was confirmed visually and evaluated as to which of evaluation criteria 1-5 the pocket angle 11 corresponds. Further, the presence or absence of perforations in the pocket 20 was confirmed visually. On the basis of these results, moldability was evaluated by the determination criteria described below. Among the following determination criteria, good or higher was deemed to be a pass (moldability is good).

### <Determination Criteria>

Excellent: Sharpness of pocket angle had an evaluation criterion of 4 or higher and there were no perforations
Good: Sharpness of pocket angle had an evaluation criterion of 3 or higher and less than 4, and there were no perforations
Fail: There was a perforation, or there were no perforations but the sharpness of the angle of the pocket was 2 or lower

### (2) Punching-Out Burr Properties

A vacuum rotary former (product name “CT 8/24”, manufactured by Mühlbauer) was used to perform punching-out in sheet samples slit into 8 mm widths in an environment with a temperature of 23° C. and a relative humidity of 50%, and burrs and fluffs around punched-out holes were evaluated. Note that punching-out was performed at a speed of 240 m/h using a punching-out device provided with a cylindrical punching-out pin with a sprocket hole pin tip diameter of 1.5 mm and a die hole with a diameter of 1.58 mm.

An image of the punched-out hole formed in the sheet described above was captured, in an illumination environment with an epi-illumination of 0%, transmission of 40%, and a ring of 0%, by using a measuring microscope (product name “MF-A1720H (image unit 6D)”, manufactured by Mitutoyo Corporation). Holes with a diameter of 1.5 mm were observed at ten locations and the number of burrs and fluffs with a length of 0.15 mm or more was counted. Further, evaluations were made in accordance with the following determination criteria, with good or higher being deemed to be a pass (generation of burrs and fluffs is inhibited).

### <Determination Criteria>

Excellent: Number of burrs, fluffs was less than six
Good: Number of burrs, fluffs was six or more and less than ten
Fail: Number of burrs, fluffs was ten or more

TABLE 1

| | | | | | Example 1 | Example 2 | Example 3 | Example 4 | Example 5 |
|---|---|---|---|---|---|---|---|---|---|
| Substrate | Constitution | Substrate | a-1 | (mass %) | 100 | 100 | 100 | 100 | 100 |
| sheet | | layer A | a-2 | | | | | | |
| | | | a-3 | | | | | | |
| | | Substrate | b-1 | | 100 | 100 | 100 | 100 | 100 |
| | | laver B | b-2 | | | | | | |
| | Configuration | Thickness of individual | | (μm) | 60 | 40 | 35 | 20 | 10 |
| | | substrate layer A | | | | | | | |
| | | Number of substrate | | (—) | 2 | 3 | 4 | 5 | 11 |
| | | layers A | | | | | | | |
| | | Thickness of individual | | (μm) | 30 | 20 | 10 | 15 | 5 |
| | | substrate layer B | | | | | | | |
| | | Number of substrate | | (—) | 1 | 2 | 3 | 4 | 10 |
| | | layers B | | | | | | | |
| | | Total number of substrate | | (—) | 3 | 5 | 7 | 9 | 21 |
| | | layers A and B laminated | | | | | | | |
| | | Average value of thickness | | (—) | 1.200 | 2.000 | 3.800 | 1.313 | 2.000 |
| | | of individual substrate | | | | | | | |
| | | layer A/average value | | | | | | | |
| | | of thickness of individual | | | | | | | |
| | | substrate layer B | | | | | | | |
| | | Thickness of substrate | | (μm) | 170 | 160 | 17O | 160 | 100 |
| | | sheet | | | | | | | |
| Conductive | Configuration | Conductive layer (both | | (—) | Y | Y | Y | Y | Y |
| layer | | surfaces) (Y/N) | | | | | | | |
| | | Average value of individual | | (μm) | 15 | 20 | 15 | 20 | 20 |
| | | layer thickness | | | | | | | |
| Total thickness of electronic device packaging sheet | | | | (μm) | 200 | 200 | 200 | 200 | 200 |
| Evaluation | Moldability | | | | Excellent | Excellent | Excellent | Excellent | Excellent |
| | Punching-out burr properties | | | | Excellent | Excellent | Excellent | Excellent | Excellent |
| | (No. of burrs) | | | | 4 | 2 | 1 | 0 | 0 |
| | | | | | Example 6 | Example 7 | Example 8 | Example 9 | Example 10 |
| Substrate | Constitution | Substrate | a-1 | (mass %) | 100 | 100 | 100 | 60 | 100 |
| sheet | | layer A | a-2 | | | | | 40 | |
| | | | a-3 | | | | | | |
| | | Substrate | b-1 | | 100 | 100 | 100 | 100 | 60 |
| | | laver B | b-2 | | | | | | 40 |

| | | | | | | | | |
|---|---|---|---|---|---|---|---|---|
| | Configuration | Thickness of individual | (μm) | 10 | 10 | 30 | 20 | 20 |
| | | substrate layer A | | | | | | |
| | | Number of substrate | (—) | 15 | 35 | 4 | 6 | 5 |
| | | layers A | | | | | | |
| | | Thickness of individual | (μm) | 1 | 3 | 10 | 15 | 15 |
| | | substrate layer B | | | | | | |
| | | Number of substrate | (—) | 14 | 34 | 4 | 4 | 4 |
| | | layers B | | | | | | |
| | | Total number of substrate | (—) | 29 | 59 | 3 | 5 | 9 |
| | | layers A and B laminated | | | | | | |
| | | Average value of thickness | (—) | 10.000 | 3.333 | 3.000 | 1.333 | 1.333 |
| | | of individual substrate | | | | | | |
| | | layer A/average value | | | | | | |
| | | of thickness of individual | | | | | | |
| | | substrate layer B | | | | | | |
| | | Thickness of substrate | (μm) | 104 | 452 | 160 | 100 | 160 |
| | | sheet | | | | | | |
| Conductive | Configuration | Conductive layer (both | (—) | Y | Y | Y | Y | Y |
| layer | | surfaces) (Y/N) | | | | | | |
| | | Average value of individual | (μm) | 15 | 24 | 20 | 20 | 20 |
| | | layer thickness | | | | | | |

| | | | | | | |
|---|---|---|---|---|---|---|
| Total thickness of electronic device packaging sheet | (μm) | 200 | 500 | 200 | 200 | 200 |

| | | | | | | |
|---|---|---|---|---|---|---|
| Evaluation | Moldability | Excellent | Excellent | Excellent | Excellent | Excellent |
| | Punching-out burr properties | Excellent | Excellent | Excellent | Excellent | Excellent |
| | (No. of burrs) | 0 | 0 | 1 | 0 | 2 |

| | | | | | Example 11 | Example 12 | Example 13 | Example 14 |
|---|---|---|---|---|---|---|---|---|
| Substrate | Constitution | Substrate | a-1 | (mass %) | 100 | 100 | | 100 |
| sheet | | layer A | a-2 | | | | | |
| | | | a-3 | | | | 100 | |
| | | Substrate | b-1 | | 100 | 100 | | 100 |
| | | laver B | b-2 | | | | 100 | |

| | | | | | | | |
|---|---|---|---|---|---|---|---|
| | Configuration | Thickness of individual | (μm) | 60 | 10 | 20 | 20 |
| | | substrate layer A | | | | | |
| | | Number of substrate | (—) | 1 | 40 | 5 | 5 |
| | | layers A | | | | | |
| | | Thickness of individual | (μm) | 30 | 1 | 15 | 15 |
| | | substrate layer B | | | | | |
| | | Number of substrate | (—) | 1 | 40 | 4 | 4 |
| | | layers B | | | | | |
| | | Total number of substrate | (—) | 2 | 20 | 3 | 3 |
| | | layers A and B laminated | | | | | |
| | | Average value of thickness | (—) | 2.000 | 10.000 | 1.333 | 1.333 |
| | | of individual substrate | | | | | |
| | | layer A/average value | | | | | |
| | | of thickness of individual | | | | | |
| | | substrate layer B | | | | | |
| | | Thickness of substrate | (μm) | 90 | 440 | 160 | 160 |
| | | sheet | | | | | |
| Conductive | Configuration | Conductive layer (both | (—) | Y | Y | Y | N |
| layer | | surfaces) (Y/N) | | | | | |
| | | Average value of individual | (μm) | 20 | 20 | 20 | — |
| | | layer thickness | | | | | |

| | | | | | |
|---|---|---|---|---|---|
| Total thickness of electronic device packaging sheet | (μm) | 150 | 500 | 200 | 180 |

| | | | | | |
|---|---|---|---|---|---|
| Evaluation | Moldability | Excellent | Excellent | Excellent | Excellent |
| | Punching-out burr properties | Good | Excellent | Good | Excellent |
| | (No. of burrs) | 4 | 1 | 8 | 0 |

TABLE 2

| | | | | | Comp Ex 1 | Comp Ex 2 | Comp Ex 3 | Comp Ex 4 |
|---|---|---|---|---|---|---|---|---|
| Substrate | Constitution | Substrate | a-1 | (mass %) | 100 | | 100 | 100 |
| sheet | | layer A | a-2 | | | 100 | | |
| | | | a-3 | | | | | |
| | | Substrate | b-1 | | | 100 | 100 | 100 |
| | | laver B | b-2 | | 100 | | | |

| | | | | | | | |
|---|---|---|---|---|---|---|---|
| | Configuration | Thickness of individual | (μm) | 20 | 20 | 6 | 75 |
| | | substrate layer A | | | | | |
| | | Number of substrate | (—) | 5 | 5 | 5 | 2 |
| | | layers A | | | | | |
| | | Thickness of individual | (μm) | 15 | 15 | 30 | 10 |
| | | substrate layer B | | | | | |
| | | Number of substrate | (—) | 4 | 4 | 4 | 1 |
| | | layers B | | | | | |
| | | Total number of substrate | (—) | 9 | 9 | 9 | 3 |
| | | layers A and B laminated | | | | | |
| | | Average value of thickness | (—) | 1.333 | 1.333 | 0.200 | 7.500 |
| | | of individual substrate | | | | | |
| | | layer A/average value | | | | | |
| | | of thickness of individual | | | | | |
| | | substrate layer B | | | | | |
| | | Thickness of substrate | (μm) | 160 | 160 | 150 | 160 |
| | | sheet | | | | | |
| Conductive | Configuration | Conductive layer (both | (—) | Y | Y | Y | Y |
| layer | | surfaces) (Y/N) | | | | | |
| | | Average value of individual | (μm) | 20 | 20 | 25 | 20 |
| | | layer thickness | | | | | |

| | | | | | |
|---|---|---|---|---|---|
| Total thickness of electronic device packaging sheet | (μm) | 200 | 200 | 200 | 200 |

| | | | | | |
|---|---|---|---|---|---|
| Evaluation | Moldability | Excellent | Fail | Fail | Excellent |
| | Punching-out burr properties | Fail | Fail | Excellent | Fail |
| | (No. of burrs) | 15 | 11 | 4 | 13 |

| | | | | | Comp Ex 5 | Comp Ex 6 | Comp Ex 7 |
|---|---|---|---|---|---|---|---|
| Substrate | Constitution | Substrate | a-1 | (mass %) | 100 | 100 | 100 |
| sheet | | layer A | a-2 | | | | |
| | | | a-3 | | | | |
| | | Substrate | b-1 | | 100 | 100 | 100 |
| | | laver B | b-2 | | | | |

| | | | | | | |
|---|---|---|---|---|---|---|
| | Configuration | Thickness of individual | (μm) | 20 | 10 | 40 |
| | | substrate layer A | | | | |
| | | Number of substrate | (—) | 8 | 3 | 2 |
| | | layers A | | | | |
| | | Thickness of individual | (μm) | 0.57 | 65 | 40 |
| | | substrate layer B | | | | |
| | | Number of substrate | (—) | 7 | 2 | 2 |
| | | layers B | | | | |
| | | Total number of substrate | (—) | 15 | 5 | 4 |
| | | layers A and B laminated | | | | |
| | | Average value of thickness | (—) | 35.088 | 0.154 | 1.000 |
| | | of individual substrate | | | | |
| | | layer A/average value | | | | |
| | | of thickness of individual | | | | |
| | | substrate layer B | | | | |
| | | Thickness of substrate | (μm) | 164 | 160 | 160 |
| | | sheet | | | | |
| Conductive | Configuration | Conductive layer (both | (—) | Y | Y | Y |
| layer | | surfaces) (Y/N) | | | | |
| | | Average value of individual | (μm) | 18 | 20 | 20 |
| | | layer thickness | | | | |

| | | | | |
|---|---|---|---|---|
| Total thickness of electronic device packaging sheet | (μm) | 200 | 200 | 200 |

| | | | | |
|---|---|---|---|---|
| Evaluation | Moldability | Excellent | Fail | Fail |
| | Punching-out burr properties | Fail | Excellent | Excelent |
| | (No. of burrs) | 15 | 1 | 2 |

As shown in Table 1, it was discovered that the electronic device packaging sheets according to Examples 1-14 which satisfy the configuration of the present invention have good moldability, and furthermore, can effectively inhibit the generation of fluffs and burrs when punching out is performed on the sheets. Meanwhile, the electronic device packaging sheets of Comparative Examples 1-7 which do not satisfy the configuration of the present invention had poor moldability or punching-out properties. From the above results, it was confirmed that the electronic device packaging sheet according to the present invention can effectively inhibit the generation of burrs and fluffs while maintaining good moldability.

### REFERENCE SIGNS LIST

10 Molded product
11 Pocket angle
20 Pocket

1. An electronic device packaging sheet provided with a substrate sheet in which a substrate layer A and a substrate layer B are alternately laminated, wherein:
the thickness of an individual substrate layer A is 10-60 μm, the thickness of an individual substrate layer B is 1-50 μm, and an average value of the thickness of an individual substrate layer A is greater than an average value of the thickness of an individual substrate layer B; and
the substrate layer A and the substrate layer B comprise a different thermoplastic resin as a main component.

2. The electronic device packaging sheet according to claim 1, wherein the number of alternately laminated layers of the substrate layer A and the substrate layer B is 3-70.

3. The electronic device packaging sheet according to claim 1, wherein the average value of the thickness of an individual substrate layer A is 1.001 times or more the average value of the thickness of an individual substrate layer B.

4. The electronic device packaging sheet according to claim 1, wherein the substrate layer A comprises an ABS-based resin as a main component.

5. The electronic device packaging sheet according to claim 1, wherein the substrate layer B comprises a thermoplastic resin other than an ABS-based resin as a main component.

6. A molded article comprising the electronic device packaging sheet according to claim 1.

7. The molded article according to claim 6, wherein the molded article is a container.

8. The molded article according to claim 6, wherein the molded article is a carrier tape.

9. The electronic device packaging sheet according to claim 2, wherein the average value of the thickness of an individual substrate layer A is 1.001 times or more the average value of the thickness of an individual substrate layer B.

10. The electronic device packaging sheet according to claim 2, wherein the substrate layer A comprises an ABS-based resin as a main component.

11. The electronic device packaging sheet according to claim 3, wherein the substrate layer A comprises an ABS-based resin as a main component.

12. The electronic device packaging sheet according to claim 2, wherein the substrate layer B comprises a thermoplastic resin other than an ABS-based resin as a main component.

13. The electronic device packaging sheet according to claim 3, wherein the substrate layer B comprises a thermoplastic resin other than an ABS-based resin as a main component.

14. The electronic device packaging sheet according to claim 4, wherein the substrate layer B comprises a thermoplastic resin other than an ABS-based resin as a main component.

15. A molded article comprising the electronic device packaging sheet according to claim 2.

16. A molded article comprising the electronic device packaging sheet according to claim 3.

17. A molded article comprising the electronic device packaging sheet according to claim 4.

18. A molded article comprising the electronic device packaging sheet according to claim 5.
